(19) United States
(12) Patent Application Publication
(10) Pub. No.: US 2026/0213153 A1
(43) Pub. Date: Jul. 23, 2026

(54) CHARGING METHOD IN ACTIVATION PROCESS OF LITHIUM SECONDARY BATTERY

(71) Applicant: SK On Co., Ltd., Seoul (KR)

(72) Inventors: Gi Su JEONG, Daejeon (KR); Jun Hui JEONG, Daejeon (KR)

(21) Appl. No.: 19/456,987

(22) Filed: Jan. 22, 2026

(30) Foreign Application Priority Data
Jan. 23, 2025 (KR) 10-2025-0010463

(51) Int. Cl. H01M 4/04; G01R 31/382; H01M 10/052

(52) U.S. Cl. CPC H01M 4/0445; G01R 31/382; H01M 10/052

(57) ABSTRACT

The present disclosure relates to a charging method in an activation process of a lithium secondary battery. The charging method in an activation process of a lithium secondary battery includes a measurement step of measuring admittance values according to a state of charge of a pre-charged lithium secondary battery, a calculation step of converting each of the admittance values and calculating converted values, a determination step of determining a second charge rate by multiplying each of the converted values by a first charge rate, and a charging step of charging the lithium secondary battery by applying the second charge rate.

### CROSS-REFERENCE TO RELATED PATENT APPLICATION

The present application claims priority under 35 U.S.C. § 119(a) to Korean patent application number 10-2025-0010463 filed on January 23, 2025, in the Ministry of Intellectual Property, the entire disclosure of which is incorporated by reference herein.

### BACKGROUND OF THE INVENTION

### 1. Field

The present disclosure relates to a charging method in an activation process of a lithium secondary battery, and more particularly, to a charging method capable of charging a pre-charged lithium secondary battery at a faster rate while preventing an increase in an amount of lithium deposition on an electrode surface.

### 2. Description of the Related Art

Lithium secondary batteries mainly use lithium-based oxides and carbon materials as anode active materials and cathode active materials, respectively. The lithium secondary battery includes: an electrode assembly including an anode plate and a cathode plate on which the anode active material and the cathode active material are applied, respectively, with a separator therebetween; and an outer material for sealing the electrode assembly with an electrolyte.

After manufacturing such a lithium secondary battery, an activation process is typically performed, and through the activation process, the structure of the lithium secondary battery is stabilized and the lithium secondary battery becomes ready for use.

The activation process is performed in various ways depending on the capacity of the lithium secondary battery, the type and electrical characteristics of the electrode material, the type and chemical characteristics of the electrolyte. However, in general, the activation process may include performing prior charging at a point in time when the electrolyte sufficiently permeates the electrode materials, and may further include processes such as aging, discharging, and degassing.

On the other hand, during prior charging in the activation process, a process of fully charging a pre-charged lithium secondary battery at a low charge rate (hereinafter, referred to as “full charging”) is performed once in order to activate the lithium secondary battery.

Here, when the lithium secondary battery is charged at an increased charge rate so as to reduce charging time for improving productivity of the lithium secondary battery, there is a problem in that lithium is deposited on an electrode surface, thereby degrading quality of the lithium secondary battery.

In order to address such a problem, a method of charging the lithium secondary battery at a relatively high charge rate while applying pressure to the lithium secondary battery and heating the lithium secondary battery has been used. However, since such a method requires additional time for pressurizing and heating the lithium secondary battery, the method does not improve productivity of the lithium secondary battery.

Therefore, there is a need to develop a charging method capable of fully charging a pre-charged lithium secondary battery at a higher speed while preventing an increase in an amount of lithium deposition on an electrode surface.

### SUMMARY OF THE INVENTION

An object of the present disclosure is to provide a charging method capable of charging a pre-charged lithium secondary battery at a higher speed while preventing an increase in an amount of lithium deposition on an electrode surface.

Another object of the present disclosure is to provide a charging method capable of improving productivity of a lithium secondary battery.

A charging method in an activation process of a lithium secondary battery according to the present disclosure may be widely applied in green technology fields using batteries, such as electric vehicles. In addition, the charging method in the activation process of the lithium secondary battery according to the present disclosure may be used in production of batteries used in environmentally friendly electric vehicles and hybrid vehicles, which suppress air pollution and greenhouse gas emissions to prevent climate change.

Embodiments of the present disclosure provide a charging method in an activation process of a lithium secondary battery, the charging method including: a measurement step of measuring admittance values according to a state of charge of a pre-charged lithium secondary battery; a calculation step of converting each of the admittance values by a predetermined ratio to calculate converted values according to the state of charge of the lithium secondary battery; a determination step of determining a second charge rate to be applied according to the state of charge during charging of the lithium secondary battery by multiplying each of the converted values by a preset first charge rate; and a charging step of charging the lithium secondary battery by applying the second charge rate according to the state of charge.

In an embodiment, the calculation step may calculate each of the converted values by dividing each of the admittance values by a minimum admittance value among the plurality of admittance values.

In an embodiment, when a state of charge of the lithium secondary battery is expressed as a percentage, a percentage of a maximally charged state of the lithium secondary battery may be 100%, and a percentage of a state of charge of the pre-charged lithium secondary battery may be a positive value less than 100%.

In an embodiment, the measurement step may measure the admittance values using a Galvanostatic Intermittent Titration Technique (GITT).

In an embodiment of the present disclosure, a charging method in an activation process of a lithium secondary battery includes: a measurement step of measuring admittance values according to a state of charge of a pre-charged lithium secondary battery; a classification step of classifying the state of charge of the lithium secondary battery into a plurality of sections; a first calculation step of calculating an average value of the admittance values according to the state of charge of the lithium secondary battery for each of the sections; a second calculation step of converting each of the average values using a preset predetermined ratio to calculate converted values for each of the sections of the lithium secondary battery; a determination step of determining a second charge rate to be applied to each of the sections during charging of the lithium secondary battery by multiplying each of the converted values by a preset first charge rate; and a charging step of charging the lithium secondary battery by applying the second charge rate to each of the sections.

In an embodiment, the second calculation step may calculate each of the converted values by dividing each of the average values by a minimum average value among the plurality of average values.

In an embodiment, the classification step may classify the state of charge of the lithium secondary battery into a plurality of sections having the same range size.

In an embodiment, when a state of charge of the lithium secondary battery is expressed as a percentage, a percentage of a maximally charged state of the lithium secondary battery may be 100%, and a percentage of a state of charge of the pre-charged lithium secondary battery may be a positive value less than 100%.

In an embodiment, the measurement step may measure the admittance values using a Galvanostatic Intermittent Titration Technique (GITT).

### BRIEF DESCRIPTION OF THE DRAWINGS

FIG. 1 is a flowchart showing a charging method in an activation process of a lithium secondary battery according to one embodiment of the present disclosure.

FIG. 2 is a graph for explaining a method for measuring admittance values according to a state of charge of the lithium secondary battery by using a Galvanostatic Intermittent Titration Technique (GITT).

FIG. 3 is a graph showing admittance values according to a state of charge of a lithium secondary battery.

FIG. 4 is a flowchart showing a charging method in an activation process of a lithium secondary battery according to another embodiment of the present disclosure.

FIG. 5 is a graph illustrating that different charge rates are applied for respective sections of a state of charge during charging of the lithium secondary battery.

FIG. 6 is a table showing charge rates applied to respective sections during charging of the lithium secondary battery.

FIG. 7 is a graph showing a voltage of a lithium secondary battery when a pre-charged lithium secondary battery is charged at a charge rate according to a reference value and a voltage of a lithium secondary battery when a pre-charged lithium secondary battery is charged at a charge rate according to the charging method of the present disclosure.

FIG. 8 is a graph showing a charging time required to fully charge a pre-charged lithium secondary battery at a charge rate according to the reference value and a charging time required to fully charge the pre-charged lithium secondary battery at a charge rate according to the charging method of the present disclosure.

### DETAILED DESCRIPTION

Hereinafter, an embodiment of the present invention will be described in detail so that a person having ordinary knowledge in the technical field to which the present invention belongs may easily practice it with reference to the attached drawings. However, the present invention may be implemented in various other forms and is not limited to the embodiments described herein. In order to clearly illustrate the present disclosure in the drawings, portions not pertinent to the description at have been omitted, and like parts throughout the specification are designated by like drawing numerals.

Throughout the specification, when a part is said to be "connected" to another part, this includes not only being "directly connected" but also being "electrically connected" with another element in between.

Throughout the specification, when a part is said to be "on" another part, this includes not only when a part is abutting another part, but also when there is another part between the two parts.

Throughout the specification, whenever a part is said to "include" a component, it is meant to be capable of further including other components, not excluding other components, unless specifically noted to the contrary. The terms "about," "substantially," "substantially," and the like, as used throughout the specification, are intended to be used at or near the numerical value when manufacturing and material tolerances inherent in the recited meanings are given, and are used for the purpose of clarity and to prevent unscrupulous infringers from taking unfair advantage of the disclosure where precise or absolute numerical values are recited. As used throughout the disclosure, the terms "steps of" or "steps of" do not mean "steps for".

Hereinafter, preferred embodiments of the present disclosure will be described in detail below with reference to the accompanying drawings and the following description. However, the disclosure is not limited to the embodiments described herein and may be embodied in other forms. Throughout the specification, like reference numerals throughout denote like components.

Hereinafter, a charging method in an activation process of a lithium secondary battery according to one embodiment of the present disclosure will be described.

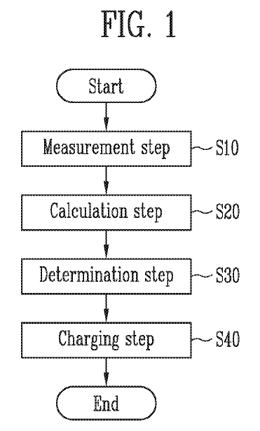

FIG. 1 is a flowchart illustrating a charging method in an activation process of a lithium secondary battery according to one embodiment of the present disclosure.

Referring to FIG. 1, the activation process of a lithium secondary battery includes a measurement step S10, a calculation step S20, a determination step S30, and a charging step S40.

First, the measurement step S10 will be described.

The measurement step S10 is a step of measuring an admittance value according to each state of charge of a pre-charged lithium secondary battery .

Pre-charging is a process of charging the lithium secondary battery so that the lithium secondary battery has a predetermined state of charge during a pre-charging process.

Prior charging is a process in which electrolyte is injected into the lithium secondary battery and then charged before electrolyte impregnation (wetting) to lower cathode potential. When electrolyte is injected into the lithium secondary battery, the electrolyte is gradually impregnated into pores of electrodes, which may oxidize and elute foreign materials or copper. Therefore, by performing the pre-charging process after the electrolyte injection and before the electrolyte impregnation is complete, the cathode potential may be lowered to prevent foreign materials or metals such as copper from eluting.

On the other hand, in the charging method in the activation process of the lithium secondary battery according to one embodiment of the present disclosure, when the state of charge of the lithium secondary battery is expressed as a percentage, a percentage of the state of charge in which the lithium secondary battery is maximally charged (fully charged) is 100%, and a percentage of the state of charge in which the pre-charging of the lithium secondary battery is completed may be a positive number less than 100%.

In the measurement step S10, the admittance value of the state of charge of the lithium secondary battery may be measured in various ways. For example, in the measurement step S10, a Galvanostatic Intermittent Titration Technique (GITT) may be utilized to measure the admittance value according to each state of charge of the lithium secondary battery.

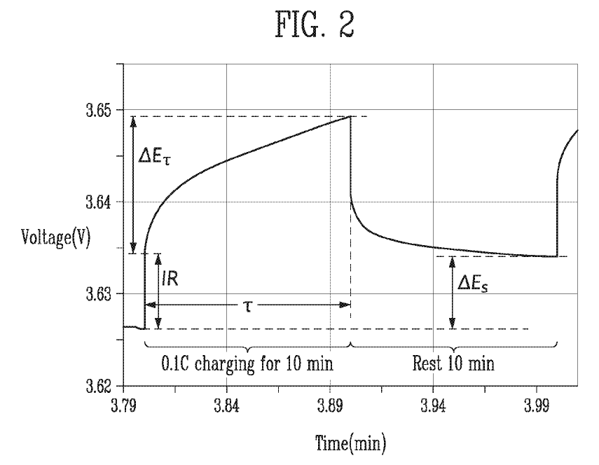

FIG. 2 is a graph for explaining a method for measuring the admittance value according to a state of charge of the lithium secondary battery by using the GITT.

Referring to FIG. 2, a pre-charged lithium secondary battery may be charged for 10 minutes at a charge rate of 0.1C (Capacity), followed by a 10 minute rest period, and the process may be repeated until a voltage of the lithium secondary battery reaches 4.2V.

Then, values of △Eτ and △Es according to each state of charge may be obtained to obtain the admittance value according to each state of charge of the lithium secondary battery. The admittance value is proportional to the square of △Eτ divided by △Es.

In this case, △Eτ is a value obtained by subtracting a voltage value of the lithium secondary battery when the lithium secondary battery having a predetermined state of charge is charged for 0.1 seconds at a charge rate of 0.1C (capacity) from a voltage value of the lithium secondary battery when the lithium secondary battery having a predetermined state of charge is charged for 10 minutes at a charge rate of 0.1C (capacity).

The calculated △Eτ value is a △Eτ value at a state of charge of the lithium secondary battery when the lithium secondary battery having a predetermined state of charge is charged for 10 minutes at a charge rate of 0.1C (capacity).

Also, △Es is a value obtained by subtracting a voltage value of the lithium secondary battery having a predetermined state of charge from a voltage value of the lithium secondary battery reached after charging the lithium secondary battery having the predetermined state of charge for 10 minutes at a charge rate of 0.1C (capacity) and then having a rest period of 10 minutes.

The calculated △Es value becomes a △Es value at a state of charge of the lithium secondary battery when the lithium secondary battery having a predetermined state of charge is charged for 10 minutes at a charge rate of 0.1C (capacity).

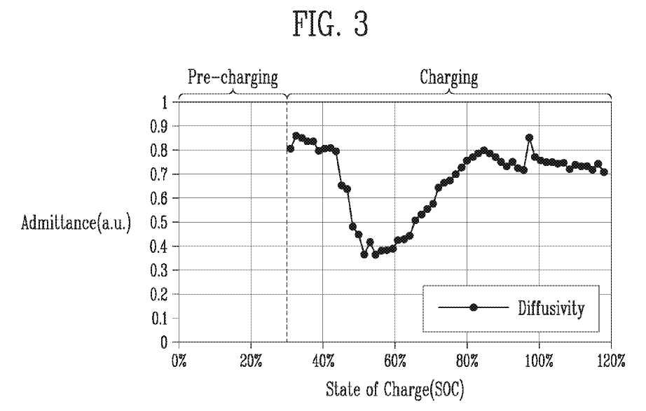

FIG. 3 is a graph showing the admittance value according to the state of charge of the lithium secondary battery.

As shown in FIG. 3, the admittance values that are measured as described above may vary depending on the state of charge of the lithium secondary battery.

Next, the calculation step S20 will be described.

The calculation step S20 is a step in which the respective admittance values measured in the measurement step S10 are converted to a predetermined ratio to calculate a conversion value according to each state of charge of the lithium secondary battery.

Specifically, in the calculation step S20, when a converted value of a minimum admittance value among a plurality of admittance values is set to 1, a converted value of each admittance value may be calculated such that a ratio between the minimum admittance value and another admittance value among the plurality of admittance values becomes a ratio between 1 and a converted value of the another admittance value.

That is, in the calculation step S20, a converted value of each admittance value may be calculated by dividing each admittance value by a minimum admittance value among a plurality of admittance values.

Next, the determination step S30 will be described.

The determination step S30 is a step of determining a second charge rate to be applied according to a state of charge during charging of the lithium secondary battery by multiplying each converted value by a preset first charge rate.

Here, although the first charge rate multiplied by each converted value is not particularly limited, the first charge rate is preferably in a range from 0.1C (capacity) to 1C (capacity) so that the lithium secondary battery may be safely charged.

Next, the charging step S40 will be described.

The charging step S40 is a step of charging the lithium secondary battery by applying a second charge rate according to the state of charge.

For example, when a percentage of the state of charge of the lithium secondary battery is 40% and the second charge rate is 0.7C, the lithium secondary battery having a percentage of the state of charge of 40% may be charged by applying the charge rate of 0.7C.

Hereinafter, a charging method in an activation process of a lithium secondary battery according to another embodiment of the present disclosure will be described.

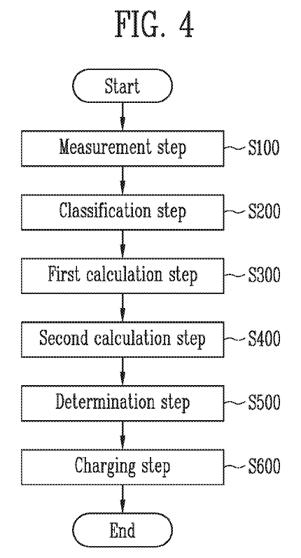

FIG. 4 is a flowchart illustrating a charging method in an activation process of a lithium secondary battery according to another embodiment of the present disclosure.

Referring to FIG. 4, the charging method in the activation process of the lithium secondary battery includes a measurement step S100, a classification step S200, a first calculation step S300, a second calculation step S400, a determination step S500, and a charging step S600.

First, the measurement step S100 will be described.

The measurement step S10 is a step of measuring an admittance value according to each state of charge of a pre-charged lithium secondary battery.

Pre-charging is a process of charging the lithium secondary battery so that the lithium secondary battery has a predetermined state of charge during a pre-charging process, and prior charging is a process in which electrolyte is injected into the lithium secondary battery and then charged before electrolyte impregnation (wetting) to lower cathode potential.

The pre-charging and the prior charging are the same as those described above in the charging method in the activation process of the lithium secondary battery according to one embodiment of the present disclosure.

On the other hand, in the charging method in the activation process of the lithium secondary battery according to another embodiment of the present disclosure, when the state of charge of the lithium secondary battery is expressed as a percentage, a percentage of the state of charge in which the lithium secondary battery is maximally charged (fully charged) is 100%, and a percentage of the state of charge in which the pre-charging of the lithium secondary battery is completed may be a positive number less than 100%.

In the measurement step S100, the admittance value of the state of charge of the lithium secondary battery may be measured in various ways. For example, in the measurement step S10, a Galvanostatic Intermittent Titration Technique (GITT) may be utilized to measure the admittance value according to each state of charge of the lithium secondary battery.

The method for measuring the admittance value according to each state of charge of the lithium secondary battery using the GITT is the same as the above-described method for measuring the admittance value according to each state of charge of the lithium secondary battery using the GITT in the activation process of the lithium secondary battery according to one embodiment of the present disclosure.

Next, the classification step S200 will be described.

The classification step S200 is a step of classifying the state of charge of the lithium secondary battery into a plurality of sections.

For example, the classification step S200 may classify the state of charge of the lithium secondary battery into a plurality of sections having different range sizes.

As another example, the classification step S200 may classify the state of charge of the lithium secondary battery into a plurality of sections having the same range size.

That is, when the state of charge of the lithium secondary battery is expressed as a percentage, the classification step S200 may classify the state of charge of the lithium secondary battery into a plurality of sections such that a value obtained by dividing, by a predetermined number, a difference between a percentage of a fully charged state of the lithium secondary battery and a percentage of a pre-charged state of the lithium secondary battery becomes a range size of each section.

Next, the first calculation step S300 will be described.

The first calculation step S300 is a step of calculating an average value of admittance values according to the state of charge of the lithium secondary battery for each section.

For example, when the state of charge of the lithium secondary battery is classified into a first section, a second section, and a third section, the first calculation step S300 may calculate each of an average value of admittance values in the first section, an average value of admittance values in the second section, and an average value of admittance values in the third section.

Next, the second calculation step S400 will be described.

The second calculation step S400 is a step of converting each average value calculated in the first calculation step S300 using a preset predetermined ratio to calculate a converted value for each of the sections of the lithium secondary battery.

Specifically, in the second calculation step S400, when a converted value of a minimum average value among a plurality of average values is set to 1, converted values of the respective average values may be calculated such that a ratio between the minimum average value and another average value among the plurality of average values corresponds to a ratio between 1 and a converted value of the another average value.

That is, in the second calculation step S400, a converted value of each average value may be calculated by dividing each average value by the minimum average value among the plurality of average values.

Next, the determination step S500 will be described.

The determination step S500 is a step of determining a second charge rate to be applied to each of the sections during charging of the lithium secondary battery by multiplying each converted value by a preset first charge rate.

Here, although the first charge rate multiplied by each converted value is not particularly limited, the first charge rate is preferably in a range from 0.1C (capacity) to 1C (capacity) so that the lithium secondary battery may be safely charged.

Next, the charging step S600 will be described.

The charging step S600 is a step in which the lithium secondary battery is charged by applying the second charge rate to each of the sections.

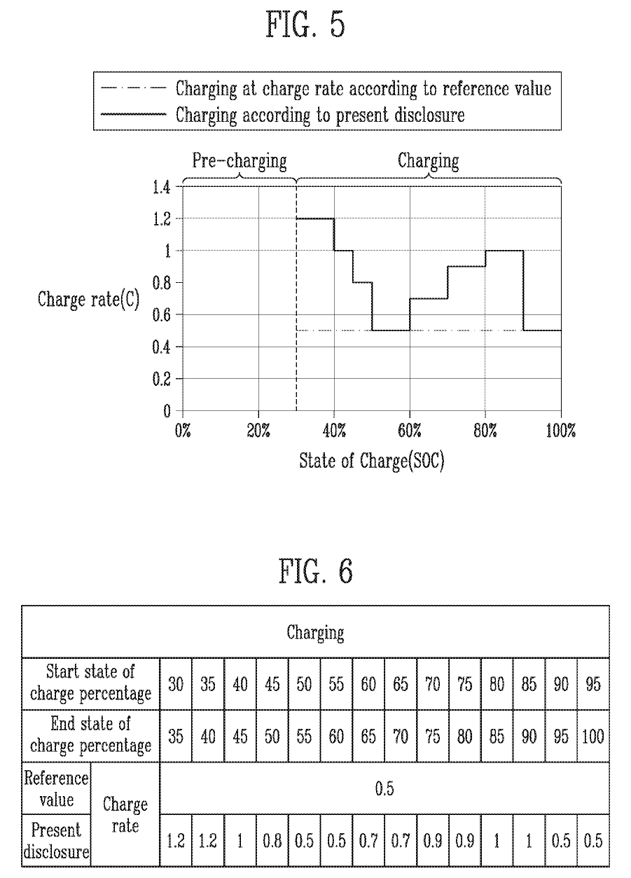

FIG. 5 is a graph illustrating that different charge rates are applied for respective sections of the state of charge during charging of the lithium secondary battery.

For example, referring to FIG. 5, the lithium secondary battery may be charged by applying a charge rate of 1.2C (capacity) in a section in which a percentage of the state of charge of the lithium secondary battery is 30% or more and 40% or less, and the lithium secondary battery may be charged by applying a charge rate of 1C (capacity) in a section in which the percentage of the state of charge of the lithium secondary battery is 80% or more and 90% or less.

Hereinafter, operations and effects of the charging method in the activation process of the lithium secondary battery according to the present disclosure will be described.

Admittance values of a pre-charged lithium secondary battery is measured according to each state of charge.

Then, converted values are calculated using respective admittance values or average values of admittance values for sections classified according to the state of charge, and a second charge rate to be applied during charging of the lithium secondary battery is determined using the converted values.

Thereafter, the lithium secondary battery is charged by applying the second charge rate according to the state of charge or according to each section.

The lithium secondary battery charged according to the above-described charging method does not suffer from a problem of quality degradation compared to a lithium secondary battery that is charged by applying a constant charge rate regardless of the state of charge of the lithium secondary battery.

FIG. 6 is a table showing charge rates applied to respective sections during charging of the lithium secondary battery.

As shown in FIG. 6, during the charging of the lithium secondary battery, a charge rate according to a preset reference value may be applied regardless of the state of charge, or different charge rates may be applied for respective sections classified according to the state of charge.

Here, when an amount of lithium deposition on an electrode surface of the lithium secondary battery charged by applying a charge rate according to the charging method of the present disclosure increases, a voltage according to a state of charge of the lithium secondary battery charged by applying the charge rate according to the charging method of the present disclosure becomes different from a voltage according to a state of charge of the lithium secondary battery charged by applying a charge rate according to a reference value.

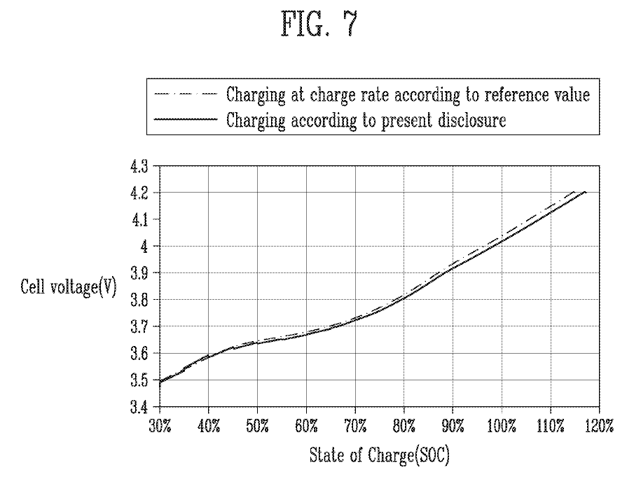

FIG. 7 is a graph showing a voltage of the lithium secondary battery when the pre-charged lithium secondary battery is charged at a charge rate according to the reference value and a voltage of the lithium secondary battery when the pre-charged lithium secondary battery is charged at a charge rate according to the charging method of the present disclosure.

However, as shown in FIG. 7, it may be seen that the lithium secondary battery charged by applying the charge rate according to the charging method of the present disclosure and the lithium secondary battery charged by applying the charge rate according to the reference value have substantially the same voltage according to the state of charge.

That is, the lithium secondary battery charged by applying the charge rate according to the charging method of the present disclosure does not suffer from a problem in which an amount of lithium deposition on the electrode surface increases, compared to the lithium secondary battery charged by applying the charge rate according to the reference value.

Also, the lithium secondary battery charged according to the charging method of the present disclosure may improve a production efficiency compared to a lithium secondary battery that is charged by applying a constant charge rate regardless of the state of charge of the lithium secondary battery.

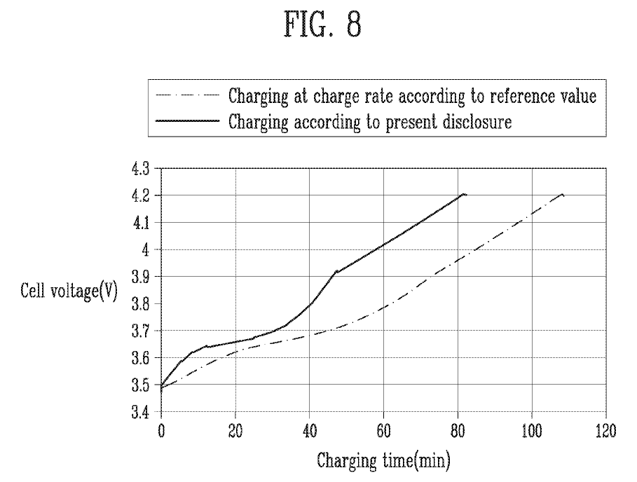

FIG. 8 is a graph showing a charging time required to fully charge a pre-charged lithium secondary battery at a charge rate according to the reference value and a charging time required to fully charge the pre-charged lithium secondary battery at a charge rate according to the charging method of the present disclosure.

Referring to FIG. 8, it may be seen that a charging time required to fully charge the lithium secondary battery at the charge rate according to the charging method of the present disclosure is reduced by approximately 20% compared to a charging time required to fully charge the lithium secondary battery at the charge rate according to the reference value.

That is, the lithium secondary battery charged by applying the charge rate according to the charging method of the present disclosure may be produced more rapidly as a time required for full charging is reduced, compared to the lithium secondary battery charged by applying the charge rate according to the reference value.

As described above, the charging method in the activation process of the lithium secondary battery according to the present disclosure provides an effect of charging the lithium secondary battery at a charge rate determined using the admittance values according to the state of charge of the lithium secondary battery, thereby preventing an increase in an amount of lithium deposition on the electrode surface while enabling the pre-charged lithium secondary battery to be charged more rapidly.

In addition, since the lithium secondary battery may be charged at a relatively high speed, the charging method provides an effect of improving productivity of the lithium secondary battery.

According to the above-described means of solving the problem of the present disclosure, the charging method in the activation process of a lithium secondary battery according to the present disclosure has the effect of charging the lithium secondary battery at a charge rate determined by using the admittance value according to the state of charge of the lithium secondary battery, thereby enabling the pre-charged lithium secondary battery to be charged more rapidly while preventing an increase in the amount of lithium deposition on the electrode surface.

Furthermore, it is possible to charge the lithium secondary battery at a relatively fast rate, thereby improving the productivity of the lithium secondary battery.

The foregoing description of the present disclosure is for illustrative purposes only, and those having ordinary knowledge in the technical field to which the present disclosure belongs will understand that it can be readily adapted to other specific forms without altering the technical ideas or essential features of the present disclosure. It should therefore be understood that the embodiments described above are exemplary in all respects and are not intended to be limiting. For example, each component described in a single form may be implemented in a distributed manner, and similarly, components described as distributed may be implemented in a combined form.

The scope of the present disclosure is indicated by the following claims rather than by the detailed description above, and the meaning and scope of the claims and all modifications or variations derived from the equivalents thereof are to be construed as being within the scope of the present disclosure.

What is claimed is:

1. A charging method in an activation process of a lithium secondary battery, the charging method comprising:
a measurement step of measuring admittance values according to a state of charge of a pre-charged lithium secondary battery;
a calculation step of converting each of the admittance values by a predetermined ratio to calculate converted values according to the state of charge of the lithium secondary battery;
a determination step of determining a second charge rate to be applied according to the state of charge during charging of the lithium secondary battery by multiplying each of the converted values by a preset first charge rate; and
a charging step of charging the lithium secondary battery by applying the second charge rate according to the state of charge.

2. The charging method of claim 1, wherein the calculation step calculates each of the converted values by dividing each of the admittance values by a minimum admittance value among the plurality of admittance values.

3. The charging method of claim 2, wherein, when a state of charge of the lithium secondary battery is expressed as a percentage,
a percentage of a maximally charged state of the lithium secondary battery is 100%, and
a percentage of a state of charge of the pre-charged lithium secondary battery is a positive value less than 100%.

4. The charging method of claim 2, wherein the measurement step measures the admittance values using a Galvanostatic Intermittent Titration Technique (GITT).

5. A charging method in an activation process of a lithium secondary battery, the charging method comprising:
a measurement step of measuring admittance values according to a state of charge of a pre-charged lithium secondary battery;
a classification step of classifying the state of charge of the lithium secondary battery into a plurality of sections;
a first calculation step of calculating an average value of the admittance values according to the state of charge of the lithium secondary battery for each of the sections;
a second calculation step of converting each of the average values using a preset predetermined ratio to calculate converted values for each of the sections of the lithium secondary battery;
a determination step of determining a second charge rate to be applied to each of the sections during charging of the lithium secondary battery by multiplying each of the converted values by a preset first charge rate; and
a charging step of charging the lithium secondary battery by applying the second charge rate to each of the sections.

6. The charging method of claim 5, wherein the second calculation step calculates each of the converted values by dividing each of the average values by a minimum average value among the plurality of average values.

7. The charging method of claim 6, wherein the classification step classifies the state of charge of the lithium secondary battery into a plurality of sections having the same range size.

8. The charging method of claim 7, wherein, when a state of charge of the lithium secondary battery is expressed as a percentage,
a percentage of a maximally charged state of the lithium secondary battery is 100%, and
a percentage of a state of charge of the pre-charged lithium secondary battery is a positive value less than 100%.

9. The charging method of claim 7, wherein the measurement step measures the admittance values using a Galvanostatic Intermittent Titration Technique (GITT).
